(19) United States
(12) Patent Application Publication
(10) Pub. No.: US 2022/0311901 A1
(43) Pub. Date: Sep. 29, 2022

(54) METHOD FOR FILE COMPRESSION IN A MULTI-FUNCTION PRINTER AND THE MULTI-FUNCTION PRINTER THEREOF

(71) Applicant: TOSHIBA TEC KABUSHIKI KAISHA, Tokyo (JP)

(72) Inventor: Satish SUKUMARAN, Bangalore (IN)

(73) Assignee: TOSHIBA TEC KABUSHIKI KAISHA, Tokyo (JP)

(21) Appl. No.: 17/703,382

(22) Filed: Mar. 24, 2022

(30) Foreign Application Priority Data
Mar. 26, 2021 (IN) 202141013341

(51) Int. Cl. H04N 1/32; G06F 16/174; H03M 7/30

(52) U.S. Cl. CPC H04N 1/32149; G06F 16/1744; H03M 7/30

(57) ABSTRACT

The present disclosure relates a method for compressing files in a multi-function printer and the multi-function printer (MFP) thereof. The method, performed by the MFP, includes: receiving one or more files for scanning; determining a size of the one or more files; determining whether the size of the one or more files is greater than or equal to a threshold value; and after scanning the one or more files, compressing the one or more files using a lossless compression technique in response to determining that the size of the one or more files is greater than or equal to the threshold value. This approach not only increases file storage capacity in the multi-function printer significantly but also reduces time required for transferring compressed files over a communication network. Consequently, this approach improves file transmission speed and network bandwidth.

### TECHNICAL FIELD

The present subject matter is generally related to multi-function printers, more particularly, but not exclusively, to a method and a multi-function printer for compressing files in the multi-function printer.

### BACKGROUND

Multi-Function Printer (MFP) has multiple functionality that includes email, fax, photocopying, printing, scanning and the like. Typically, the MFP has a limited memory for storing files. For instance, when files are considered for Scan jobs such as Scan to File or Scan to Email with the size of the files more than the available memory for storage then the current Scan job may lead to Scan job failure. This failure most often results in generating Scan job error log containing message such as job cancelled, or message size exceeded limit or maximum size. Presently, the Scan job error log is created only at the end of the Scan job process. The user performing the Scan job is not notified in advance of any warning about the file size being scanned is more than the available memory in the MFP for storage. The user is notified about the Scan job status only after completion of the Scan job process, making this approach a time-consuming process with an undesirable outcome for the user.

The information disclosed in this background of the disclosure section is for enhancement of understanding of the general background of the invention and should not be taken as an acknowledgement or any form of suggestion that this information forms the prior art already known to a person skilled in the art.

### SUMMARY

In an embodiment, the present disclosure may relate to a method for compressing files in a multi-function printer. The method includes receiving one or more files for scanning and determining size of the one or more files received for scanning. Thereafter, the method comprising determining whether the size of the one or more files is greater than or equal to a threshold value and compressing the one or more files after scanning using a lossless compression technique when the size of the one or more files is greater than or equal to the threshold value.

In an embodiment, the present disclosure may relate to a multi-function printer for compressing files in the multi-function printer. The multi-function printer may include a processor and a memory communicatively coupled to the processor, wherein the memory stores processor-executable instructions, which on execution, cause the processor to receive one or more files for scanning and determine size of the one or more files received for scanning. Thereafter, the multi-function printer is configured to determine whether the size of the one or more files is greater than or equal to a threshold value and compress the one or more files after scanning using a lossless compression technique when the size of the one or more files is greater than or equal to the threshold value.

In an embodiment, the present disclosure relates to a non-transitory computer readable medium including instructions stored thereon that when processed by at least one processor may cause a multi-function printer to receive one or more files for scanning and determine size of the one or more files received for scanning. Thereafter, the instruction causes the processor to determine whether the size of the one or more files is greater than or equal to a threshold value and compress the one or more files after scanning using a lossless compression technique when the size of the one or more files is greater than or equal to the threshold value.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE ACCOMPANYING DRAWINGS

The accompanying drawings, which are incorporated in and constitute a part of this disclosure, illustrate exemplary embodiments and together with the description, serve to explain the disclosed principles. In the figures, the left-most digit(s) of a reference number identifies the figure in which the reference number first appears. The same numbers are used throughout the figures to reference like features and components. Some embodiments of system and/or methods in accordance with embodiments of the present subject matter are now described below, by way of example only, and with reference to the accompanying figures.

FIG. 1 illustrates an exemplary environment for compressing files in a multi-function printer in accordance with some embodiments of the present disclosure.

FIG. 2 shows a detailed block diagram of a multi-function printer in accordance with some embodiments of the present disclosure.

FIG. 3 illustrates a flowchart showing a method for compressing files in a multi-function printer in accordance with some embodiments of present disclosure.

It should be appreciated by those skilled in the art that any block diagrams herein represent conceptual views of illustrative systems embodying the principles of the present subject matter. Similarly, it will be appreciated that any flowcharts, flow diagrams, state transition diagrams, pseudo code, and the like represent various processes which may be substantially represented in computer readable medium and executed by a computer or processor, whether or not such computer or processor is explicitly shown.

### DETAILED DESCRIPTION

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood, however that it is not intended to limit the disclosure to the particular forms disclosed, but on the contrary, the disclosure is to cover all modifications, equivalents, and alternatives falling within the scope of the disclosure.

The terms “comprises”, “comprising”, or any other variations thereof, are intended to cover a non-exclusive inclusion, such that a setup, device or method that comprises a list of components or steps does not include only those components or steps but may include other components or steps not expressly listed or inherent to such setup or device or method. In other words, one or more elements in a system or apparatus proceeded by “comprises . . . a” does not, without more constraints, preclude the existence of other elements or additional elements in the system or method.

In the following detailed description of the embodiments of the disclosure, reference is made to the accompanying drawings that form a part hereof, and in which are shown by way of illustration specific embodiments in which the disclosure may be practiced. These embodiments are described in sufficient detail to enable those skilled in the art to practice the disclosure, and it is to be understood that other embodiments may be utilized and that changes may be made without departing from the scope of the present disclosure. The following description is, therefore, not to be taken in a limiting sense.

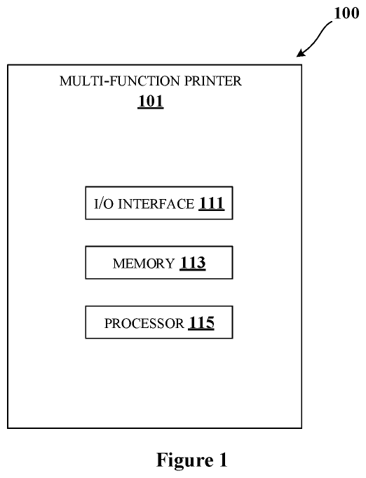

FIG. 1 illustrates an exemplary environment for compressing files in a multi-function printer in accordance with some embodiments of the present disclosure.

As shown in the FIG. 1, the environment 100 includes a Multi-Function Printer (MFP) 101. The MFP 101 may refer to a device or a machine that is capable of multiple functionalities through units that include, but is not limited to, a scanner unit, a printer unit, a copier unit, a fax unit and a network unit. The MFP 101 may, also, be called a multi-function product, a multi-function device or a multi-functional peripheral.

In the embodiment, the MFP 101 may receive scan data for scanning from one or more sources. Here, the scan data may refer to one or more files. The one or more sources may be an Automatic Document Feeder (ADF) or a user initiating scanning of the scan data at the MFP 101 through a user interface on a display panel (not shown in FIG. 1) attached of the MFP 101. The MFP 101 may include an I/O interface 111 (alternatively, referred as a user interface), a memory 113 and a processor 115. The I/O interface 111 may be configured to receive the scan data from the MFP 101.

The scan data received by the I/O interface 111 may be stored in the memory 113. The memory 113 may be communicatively coupled to the processor 115 of the MFP 101. The memory 113 may, also, store processor instructions which may cause the processor 115 to execute the instructions for compressing files in the MFP 101. The memory 113 may include, without limitation, memory drives, removable disc drives, etc. The memory drives may further include a drum, magnetic disc drive, magneto-optical drive, optical drive, Redundant Array of Independent Discs (RAID), solid-state memory devices, solid-state drives, etc. In one embodiment, the memory 113 may include Hard Disk or Solid-State Drive (SSD) of the MFP 101.

The processor 115 may include at least one data processor for compressing files in the MFP 101. The processor 115 may include specialized processing units such as integrated system (bus) controllers, memory management control units, floating point units, graphics processing units, digital signal processing units, etc.

Hereafter, the operation of the MFP 101 is explained below.

When a user wants to scan one or more files, the user may provide the one or more files to the MFP 101. The MFP 101 receives the one or more files for scanning. Thereafter, the MFP 101 determines size of the one or more files received for scanning. Subsequently, the MFP 101 determines whether the size of the one or more files is greater than or equal to a threshold value. The threshold value may be based on a scanning job type that a user performs on the MFP 101. For instance, if the scanning job type is Scan to File, the threshold value is set based on memory storage space available in the MFP 101 for storing files. If the scanning job type is Scan to Email, the threshold value is set based on file size permitted as an email attachment. The Scan to File is one of the scanning agents where the user is able to scan one or more files and store them in local network folder of the MFP 101. The Scan to Email is one of the scanning agents where a user is able to scan one or more files and sent them over an Email as an attachment. The available storage space for Scan to File job may be more than the Scan to Email job. When the size of the one or more files is greater than or equal to the threshold value, the MFP 101 compresses the one or more files after scanning using a lossless compression technique automatically. The lossless compression technique is one of, but not limited to, a Run-length Encoding (RLE) technique, a Lempel-Ziv-Welch (LZW) compression technique, a Huffman Coding technique and an Arithmetic Encoding technique. As an example, the compressing of the one or more files is into a ZIP file format. Based on the scanning job type that a user performs of the MFP 101, the MFP 101 either transmits or stores the compressed one or more files. In detail, when the scanning job type is Scan to Email, the MFP 101 transmits the compressed one or more files as an email attachment through a communication network. When the scanning job type is Scan to File, the MFP 101 stores the compressed one or more files in the memory 113 of the MFP 101. The communication network may include, but is not limited to, a direct interconnection, an e-commerce network, a Peer-to-Peer (P2P) network, Local Area Network (LAN), Wide Area Network (WAN), wireless network (for example, using Wireless Application Protocol), Internet, Wi-Fi, Bluetooth and the like.

However, when the size of the one or more files is less than the threshold value, the MFP 101 retains the size of the one or more files after scanning. Based on the scanning job type that a user performs on the MFP 101, the MFP 101 either transmits or stores the scanned one or more files. In detail, when the scanning job type is Scan to Email, the MFP 101 transmits the scanned one or more files as an email attachment through a communication network. When the scanning job type is Scan to File, the MFP 101 stores the scanned one or more files in the memory 113 of the MFP 101.

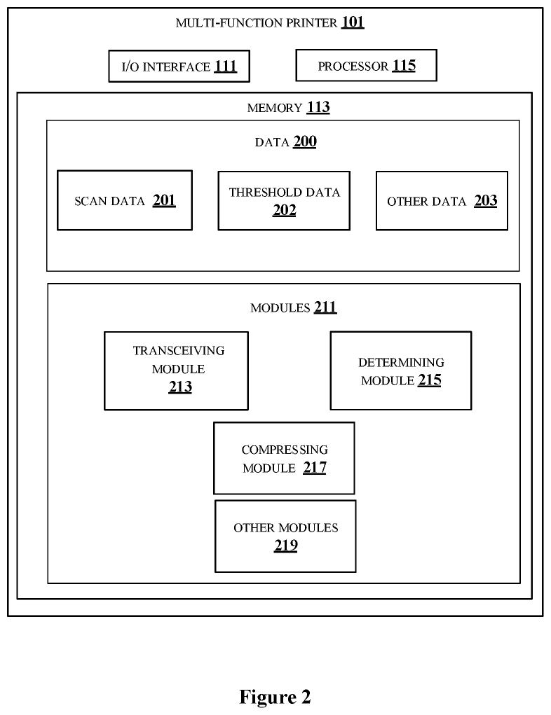

FIG. 2 shows a detailed block diagram of a multi-function printer in accordance with some embodiments of the present disclosure.

The MFP 101, in addition to the I/O interface 111 and processor 115 described above, may include data 200 and one or more modules 211, which are described herein in detail. In the embodiment, the data 200 may be stored within the memory 113. The data 200 may include, for example, scan data 201, threshold data 202 and other data 203.

The scan data 201 may include one or more files received for scanning at the MFP 101. The one or more files received is stored as the scan data 201.

The threshold data 202 may include threshold value. The threshold value may be based on a scanning job type that a user performs on the MFP 101. For instance, if the scanning job type is Scan to File, the threshold value is set based on memory storage space available in the MFP 101 for storing files. For example, Scan to File job may restrict the size of file to 1 GB so in this case the threshold value may be 1 GB. If the scanning job type is Scan to Email, the threshold value is set based on file size permitted as an email attachment. For example, Scan to Email job may restrict the size of file attachments to 5 MB so in this case the threshold value may be 5 MB.

The other data 203 may store data, including temporary data and temporary files, generated by one or more modules 211 for performing the various functions of the MFP 101.

In the embodiment, the data 200 in the memory 113 are processed by the one or more modules 211 present within the memory 113 of the MFP 101. In the embodiment, the one or more modules 211 may be implemented as dedicated hardware units. As used herein, the term module refers to an Application Specific Integrated Circuit (ASIC), an electronic circuit, a Field-Programmable Gate Arrays (FPGA), Programmable System-on-Chip (PSoC), a combinational logic circuit, and/or other suitable components that provide the described functionality. In some implementations, the one or more modules 211 may be communicatively coupled to the processor 115 for performing one or more functions of the MFP 101. The said modules 211 when configured with the functionality defined in the present disclosure will result in a novel hardware.

In one implementation, the one or more modules 211 may include, but are not limited to, a transceiving module 213, a determining module 215 and a compressing module 217. The one or more modules 211 may, also, include other modules 219 to perform various miscellaneous functionalities of the MFP 101.

The transceiving module 213 may be a combination of two modules: (1) a transmitting module to transmit the one or more files and (2) a receiving module to receive the one or more files. The transceiving module 213 may receive the one or more files for scanning from one or more sources. Here, the one or more sources may be an Automatic Document Feeder (ADF) or a user initiating scanning of the one or more files at the MFP 101 through the user interface 111 on a display panel attached of the MFP 101. Furthermore, the transceiving module 213 may receive compressed one or more files from the compressing module 217 for transmitting the compressed one or more files as an email attachment. Subsequently, the transceiving module 213 may transmit the compressed one or more files as an email attachment through a communication network when a scanning job type is Scan to Email i.e., to transmit the compressed one or more files as an email attachment. Analogously, the transceiving module 213 may receive scanned one or more files from the compressing module 217 for transmitting the scanned one or more files as an email attachment. Subsequently, the transceiving module 213 may transmit the scanned one or more files as an email attachment through the communication network when the scanning job type is Scan to Email i.e., to transmit the scanned one or more files as an email attachment. The communication network may include, but is not limited to, a direct interconnection, an e-commerce network, a Peer-to-Peer (P2P) network, Local Area Network (LAN), Wide Area Network (WAN), wireless network (for example, using Wireless Application Protocol), Internet, Wi-Fi, Bluetooth and the like.

The determining module 215 may determine size of one or more files received for scanning from the transceiving module 213. Subsequently, the determining module 215 may determine whether the size of the one or more files is greater than or equal to a threshold value. The threshold value may be based on a scanning job type that a user performs on the MFP 101. For instance, if the scanning job type is Scan to File, the threshold value is set based on memory storage space available in the MFP 101 for storing files. If the scanning job type is Scan to Email, the threshold value is set based on file size permitted as an email attachment. The threshold value for Scan to File scanning job type and Scan to Email scanning job type may be adjusted by a user.

The compressing module 217 may compress the one or more files after scanning using a lossless compression technique when the size of the one or more files is greater than or equal to the threshold value. Subsequently, the compressing module 217 may store the compressed one or more files in the memory 113 of the MFP 101 when the scanning job type is Scan to File i.e., is to save the compressed one or more files in the MFP 101. In case, the scanning job type is Scan to Email i.e., is to transmit the compressed one or more files as an email attachment, the compressing module 217 may send the compressed one or more files to the transceiving module 213 for transmitting the compressed one or more files as an email attachment. The lossless compression technique is one of, but not limited to, a Run-length Encoding (RLE) technique, a Lempel-Ziv-Welch (LZW) compression technique, a Huffman Coding technique and an Arithmetic Encoding technique. The compressing of the one or more files may be into a ZIP file format. Furthermore, the compressing module 217 may retain the size of the one or more files after scanning when the size of the one or more files is less than the threshold value. Subsequently, the compressing module 217 may store scanned one or more files in the memory 113 of the MFP 101 when the scanning job type is Scan to File i.e., is to save the scanned one or more files in the MFP 101. In case, the scanning job type is Scan to Email i.e., is to transmit the scanned one or more files, the compressing module 217 may send the scanned one or more files to the transceiving module 213 for transmitting the scanned one or more files as an email attachment.

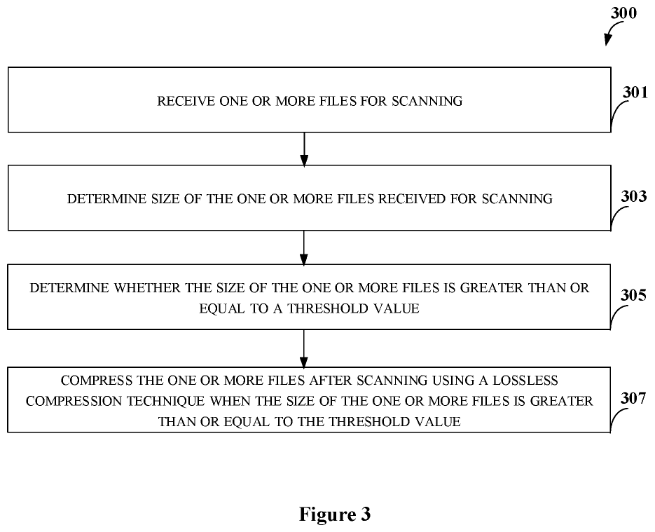

FIG. 3 illustrates a flowchart showing a method for compressing files in a multi-function printer in accordance with some embodiments of present disclosure.

As illustrated in FIG. 3, the method 300 includes one or more blocks for compressing files in the MFP 101. The method 300 may be described in the general context of computer executable instructions. Generally, computer executable instructions can include routines, programs, objects, components, data structures, procedures, modules, and functions, which perform particular functions or implement particular abstract data types.

The order in which the method 300 is described is not intended to be construed as a limitation, and any number of the described method blocks can be combined in any order to implement the method. Additionally, individual blocks may be deleted from the methods without departing from the scope of the subject matter described herein. Furthermore, the method can be implemented in any suitable hardware, software, firmware, or combination thereof.

At block 301, the transceiving module 213 may receive one or more files for scanning.

At block 303, the determining module 215 may determine size of the one or more files received for scanning.

At block 305, the determining module 215 may check whether the size of the one or more files is greater than or equal to a threshold value. The threshold value may be based on a scanning job type that a user performs on the MFP 101. For instance, if the scanning job type is Scan to File, the threshold value is set based on memory storage space available in the MFP 101 for storing files. If the scanning job type is Scan to Email, the threshold value is set based on file size permitted as an email attachment.

At block 307, the compressing module 217 may compress the one or more files after scanning using a lossless compression technique when the size of the one or more files is greater than or equal to the threshold value. The lossless compression technique may be one of a Run-length Encoding (RLE) technique, a Lempel-Ziv-Welch (LZW) compression technique, a Huffman Coding technique and an Arithmetic Encoding technique. The compressing of the one or more files may be into a ZIP file format.

Some of the advantages of the present disclosure are listed below.

The present disclosure increases file storage capacity in the MFP significantly.

The present disclosure reduces time required for transferring compressed files over communication network, consequently, improving file transmission speed.

Use of lossless compression technique in the present disclosure improves file security and prevents loss of any original information upon decompression.

The present disclosure allows compression of files without any quality loss, as a result, original data/information in the files are perfectly reconstructed from the compressed files.

Use of file size checking before scanning and compressing after scanning using compression technique based on the file size checking result prevents any scan job failure or insufficient storage errors or even a job cancellation due to insufficient storage or file size limitation in an MFP. Consequently, this approach saves ample amount of time and also, amount of rework to get the scanning job done again. Additionally, use of compression technique in present disclosure leads to reductions in storage hardware, data transmission time, and communication bandwidth. For instance, compressed files require significantly less storage capacity than uncompressed files, resulting in a significant decrease in expenses for storage. A compressed file, also, requires less time for transfer while consuming less network bandwidth. This helps in efficient utilization of network bandwidth.

Furthermore, one or more computer-readable storage media may be utilized in implementing embodiments consistent with the present disclosure. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., be non-transitory. Examples include Random Access Memory (RAM), Read-Only Memory (ROM), volatile memory, non-volatile memory, hard drives, CD ROMs, DVDs, flash drives, disks, and any other known physical storage media.

The described operations may be implemented as a method, system or article of manufacture using standard programming and/or engineering techniques to produce software, firmware, hardware, or any combination thereof. The described operations may be implemented as code maintained in a “non-transitory computer readable medium”, where a processor may read and execute the code from the computer readable medium. The processor is at least one of a microprocessor and a processor capable of processing and executing the queries. A non-transitory computer readable medium may include media such as magnetic storage medium (e.g., hard disk drives, floppy disks, tape, etc.), optical storage (CD-ROMs, DVDs, optical disks, etc.), volatile and non-volatile memory devices (e.g., EEPROMs, ROMs, PROMs, RAMs, DRAMs, SRAMs, Flash Memory, firmware, programmable logic, etc.), etc. Further, non-transitory computer-readable media include all computer-readable media except for a transitory. The code implementing the described operations may further be implemented in hardware logic (e.g., an integrated circuit chip, Programmable Gate Array (PGA), Application Specific Integrated Circuit (ASIC), etc.).

The terms “an embodiment”, “embodiment”, “embodiments”, “the embodiment”, “the embodiments”, “one or more embodiments”, “some embodiments”, and “one embodiment” mean “one or more (but not all) embodiments of the invention(s)” unless expressly specified otherwise.

The terms “including”, “comprising”, “having” and variations thereof mean “including but not limited to”, unless expressly specified otherwise.

The enumerated listing of items does not imply that any or all of the items are mutually exclusive, unless expressly specified otherwise.

The terms “a”, “an” and “the” mean “one or more”, unless expressly specified otherwise.

A description of an embodiment with several components in communication with each other does not imply that all such components are required. On the contrary, a variety of optional components are described to illustrate the wide variety of possible embodiments of the invention.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article or a different number of devices/articles may be used instead of the shown number of devices or programs. The functionality and/or the features of a device may be alternatively embodied by one or more other devices which are not explicitly described as having such functionality/features. Thus, other embodiments of the invention need not include the device itself.

The illustrated operations of FIG. 3 show certain events occurring in a certain order. In alternative embodiments, certain operations may be performed in a different order, modified or removed. Moreover, steps may be added to the above-described logic and still conform to the described embodiments. Further, operations described herein may occur sequentially or certain operations may be processed in parallel. Yet further, operations may be performed by a single processing unit or by distributed processing units.

Finally, the language used in the specification has been principally selected for readability and instructional purposes, and it may not have been selected to delineate or circumscribe the inventive subject matter. It is therefore intended that the scope of the invention be limited not by this detailed description, but rather by any claims that issue on an application based here on. Accordingly, the disclosure of the embodiments of the invention is intended to be illustrative, but not limiting, of the scope of the invention, which is set forth in the following claims.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

### REFERRAL NUMERALS

| Reference number | Description |
|---|---|
| 100 | Environment |
| 101 | Multi-function printer |
| 111 | I/O interface |
| 113 | Memory |
| 115 | Processor |
| 200 | Data |
| 201 | Scan data |
| 202 | Threshold data |
| 203 | Other data |
| 211 | Modules |
| 213 | Transceiving module |
| 215 | Determining module |
| 217 | Compressing module |
| 219 | Other modules |

What is claimed is:

1. A method for compressing files in a Multi-Function printer (MFP), the method comprising:
receiving, by a Multi-Function printer (MFP), one or more files for scanning;
determining, by the MFP, a size of the one or more files;
determining, by the MFP, whether the size of the one or more files is greater than or equal to a threshold value; and
after scanning the one or more files, compressing, by the MFP, the one or more files using a lossless compression technique in response to determining that the size of the one or more files is greater than or equal to the threshold value.

2. The method of claim 1, wherein the lossless compression technique includes one of: a Run-length Encoding (RLE) technique, a Lempel-Ziv-Welch (LZW) compression technique, a Huffman Coding technique, or an Arithmetic Encoding technique.

3. The method of claim 1, wherein the one or more files are compressed into a ZIP file format.

4. The method of claim 1, further comprising:
retaining, by the MFP, the size of the one or more files in response to determining that the size of the one or more files is less than the threshold value.

5. The method of claim 1, wherein the threshold value is determined based on a scanning job type that a user performs on the MFP.

6. The method of claim 1, further comprising:
transmitting, by the MFP, the one or more compressed files as an email attachment in response to identifying a scanning job type of transmitting the one or more compressed files; and
storing, by the MFP, the one or more compressed files in a memory of the MFP in response to identifying that the scanning job type includes saving the one or more compressed files in the MFP.

7. A Multi-Function printer (MFP) for compressing files in the MFP, the MFP comprising:
a processor; and
a memory communicatively coupled to the processor, wherein the memory stores processor-executable instructions, when executed, cause the processor to:
receive one or more files for scanning;
determine size of the one or more files;
determine whether the size of the one or more files is greater than or equal to a threshold value; and
after scanning the one or more files, compress the one or more files using a lossless compression technique in response to determining that the size of the one or more files is greater than or equal to the threshold value.

8. The MFP of claim 7, wherein the lossless compression technique is one of: a Run-length Encoding (RLE) technique, a Lempel-Ziv-Welch (LZW) compression technique, a Huffman Coding technique or an Arithmetic Encoding technique.

9. The MFP of claim 7, wherein the one or more files are compressed into a ZIP file format.

10. The MFP of claim 7, wherein the processor is configured to:
retain the size of the one or more files in response to determining that the size of the one or more files is less than the threshold value.

11. The MFP of claim 7, wherein the threshold value is determined based on a scanning job type that a user performs on the MFP.

12. The MFP of claim 7, wherein the processor is configured to
transmit the one or more compressed files as an email attachment in response to identifying a scanning job type of transmitting the one or more compressed files; and
store the one or more compressed files in the memory of the MFP in response to identifying that the scanning job type includes saving the one or more compressed files in the MFP.

13. A non-transitory computer readable medium including instruction stored thereon that when processed by at least one processor causes a Multi-Function printer (MFP) to perform a method comprising:
receiving one or more files for scanning;
determining size of the one or more files;
determining whether the size of the one or more files is greater than or equal to a threshold value; and
after scanning the one or more files, compressing the one or more files using a lossless compression technique in response to determining that the size of the one or more files is greater than or equal to the threshold value.

14. The medium of claim 13, wherein the lossless compression technique is one of: a Run-length Encoding (RLE) technique, a Lempel-Ziv-Welch (LZW) compression technique, a Huffman Coding technique or an Arithmetic Encoding technique.

15. The medium of claim 13, wherein the one or more files are compressed into a ZIP file format.

16. The medium of claim 13, wherein the method further comprises:
retaining the size of the one or more files after scanning in response to determining that the size of the one or more files is less than the threshold value.

17. The medium of claim 13, wherein the threshold value is determined based on a scanning job type that a user performs on the MFP.

18. The medium of claim 13, wherein the method further comprises:
transmitting the one or more compressed files as an email attachment in response to identifying a scanning job type of transmitting the one or more compressed files; and
storing the one or more compressed files in a memory of the MFP in response to identifying that the scanning job type includes saving the one or more compressed files in the MFP.
